(19) United States
(12) Patent Application Publication
(10) Pub. No.: US 2012/0160167 A1
(43) Pub. Date: Jun. 28, 2012

(54) External Heating of Substrate Tubes in Plasma Chemical Vapor Deposition Processes

(75) Inventors: John Alonzo, Somerset, NJ (US); James Fleming, Westfield, NJ (US); George Zydzik, Columbia, NJ (US)

(73) Assignee: OFS FITEL LLC, Norcross, GA (US)

(21) Appl. No.: 12/979,989

(22) Filed: Dec. 28, 2010

(51) Int. Cl. C23C 16/513

(52) U.S. Cl. 118/723 I; 118/723 R

(57) ABSTRACT

A PCVD apparatus including an insulative covering disposed to surround at least a portion of the substrate tube and provide external heating of the substrate tube during the deposition process. The insulative covering functions to capture and retain the external thermal energy created by the plasma process. As a result, the areas of the substrate tube that are removed from the current location of the plasma absorb this captured thermal energy and remain at an essentially constant temperature until the next pass of the work coil.

### TECHNICAL FIELD

The present invention relates to optical preform fabrication utilizing a plasma chemical vapor deposition (PCVD) process and, more particularly, to an apparatus providing external heating of the preform substrate during the deposition process.

### BACKGROUND OF THE INVENTION

One way of manufacturing an optical fiber preform is known in the art as the Plasma Chemical Vapor Deposition (PCVD) process. According to this process, one or more doped or undoped glass layers are deposited onto the interior of a substrate tube using low-pressure plasma in the glass substrate tube. After the glass layers have been deposited onto the interior of the glass substrate tube, the glass substrate tube is subsequently contracted by heating into a solid rod. In one embodiment, the solid rod may be externally provided with an additional amount of glass (i.e., by means of an external vapor deposition process), or by using one or more preformed glass tubes, thereby obtaining a composite preform. From this preform, one end is heated and drawn down in diameter to produce optical fibers.

The plasma is created by an RF field generator that surrounds a glass substrate tube. The RF generator couples the high-frequency energy into the plasma. At one end of the substrate tube, the doped or undoped reactive gases are supplied, after which a reaction takes place under the influence of the plasma, and doped or undoped glass layers are deposited onto the interior of the substrate tube. The other end of the substrate tube is connected to a vacuum pump so that a reduced pressure (e.g., between 5 and 50 mbar) is provided in the interior of the substrate. The generator is moved reciprocally in the longitudinal direction of the substrate tube so that a thin glass layer is deposited onto the interior of the substrate tube with every transversal.

It has been found that to optimize the deposited material characteristics of the deposited glass using the PCVD method, the substrate needs to be heated to (and preferably maintained at) a constant temperature in the range of the glass transition temperature of the deposited glass during the deposition process. In particular, the uniform substrate heating ensures smooth, bubble-free deposition of the glass as it is being fused to the inner substrate wall.

Several prior art methods are available for providing the substrate heating. For example, the entire assembly—substrate and work coil—can be placed in a temperature-controlled furnace that is maintained at the desired temperature. While this method provides the desired substrate heating, problems arise with the need to also expose the work coil to the elevated temperature. That is, the work coil assembly needs to be insulated and cooled so that it is not destroyed. Additionally, the need to locate the entire assembly in a furnace makes it difficult for an individual to observe the substrate during the deposition process.

Alternatively, an external burner (such as an oxyhydrogen torch) may be added to the arrangement and caused to traverse the substrate tube in advance of the work coil to heat the substrate. This heating may not be as uniform as desired (or as efficient), and requires additional energy and expense to deploy.

It is also possible to utilize substrate tubes with relatively large wall thicknesses to provide sufficient thermal mass to retain the heat from previous passes of the work coil. However, this approach is also problematic since it unduly restricts the tube sizes that can be used (since the initial wall thickness will increase significantly throughout the deposition process).

### SUMMARY OF THE INVENTION

The needs remaining in the prior art are addressed by the present invention which relates to optical fiber preform fabrication utilizing a plasma chemical vapor deposition (PCVD) process and, more particularly, to a PCVD apparatus including a insulative covering disposed to surround at least a portion of the substrate tube and provide external heating of the substrate tube during the deposition process.

A standard PCVD process is known to generate a considerable amount of thermal energy; the plasma fireball itself is a direct source of heat, while the substrate tube is an indirect source (convective and radiative) of heat. In accordance with the present invention, therefore, an insulative covering functions to capture and retain this thermal energy. As a result, the areas of the substrate tube that are removed from the current location of the plasma will absorb this captured thermal energy from the insulative covering. After a short, gradual heating period prior to deposition where the plasma is traversed reciprocally, the substrate remains at an essentially constant temperature until the next pass of the work coil.

The insulative covering is configured to only partially surround the substrate tube so that operating personnel are able to directly observe the deposition process. The covering may be in the form of a single piece of insulative material disposed along the length of the substrate tube (not necessarily along the entire length of the tube, as a matter of design choice). Alternatively, the insulative covering may comprise two or more separate longitudinal segments, with a separation between segments sufficient to allow for observation of the deposition process. The insulative covering may maintain a fixed relationship with the substrate tube, or may be adjustable (in terms of separation between the covering and the substrate, for example) if need be. In one embodiment, the insulative covering may be at least in part a transparent material that allows for unobstructed observation of both the plasma and the substrate.

The separation distance between the insulative covering and the substrate is also controlled to provide the desired degree of substrate heating. The material used to form the insulative covering is also a design consideration and will factor into the determination of the proper separation distance. Supplemental heating or cooling of the insulative covering itself may be utilized to assist in maintaining a uniform substrate tube temperature.

Other and further aspects and advantages of the present invention will become apparent during the course of the following discussion and by reference to the accompanying drawings.

### BRIEF DESCRIPTION OF THE DRAWINGS

Referring now to the drawings,

FIG. 1 illustrates an exemplary PCVD system incorporating the insulative covering of the present invention;

FIG. 2 is a simplified, cut-away side view of the arrangement of FIG. 1, illustrating the placement of the insulative covering around the substrate;

FIG. 3 is a cut-away side view of an alternative embodiment of the present invention, using separate sections of covering to surround the substrate; and

FIG. 4 is a simplified side view of a combination of a substrate tube and insulating covering, illustrating an embodiment with a variable spacing in the longitudinal direction between the substrate tube and the insulative covering.

### DETAILED DESCRIPTION

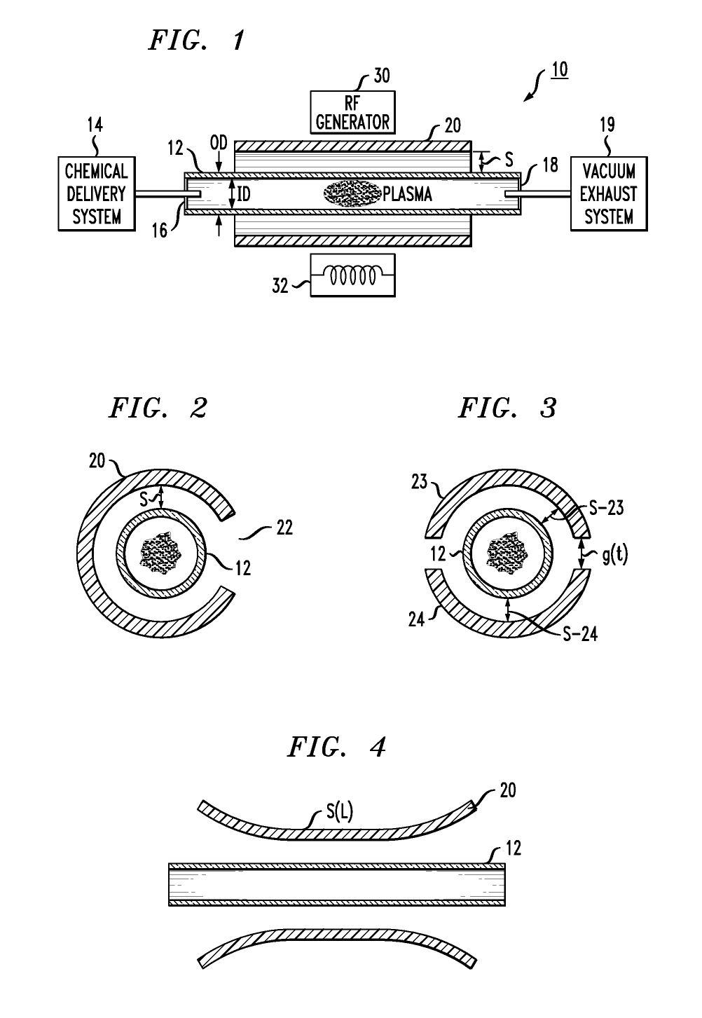

FIG. 1 illustrates an exemplary PCVD system 10 incorporating an insulative covering 20 in accordance with the teachings of the present invention. A glass tube 12 is used in apparatus 10 as the substrate tube within which the deposition will occur, where the inner diameter (ID) and outer diameter (OD) of substrate tube 12 are known parameters having an effect on the temperature of the inside wall and the reaction chemistry at the wall's surface. These factors are then considered with the type and shape of material used to form insulative covering 20, as well as the separation between insulative covering 20 and substrate tube 12, as will be discussed below.

Apparatus 10 further comprises a chemical delivery system 14 to deliver one or more chemical reactants (such as GeCl₄, SiCl₄, C₂F₆, SiF₄ and O₂) into substrate tube 12 through a first rotating seal 16 formed within a first end of tube 12. Although not shown in FIG. 1 (and not essential to the operation of the apparatus), substrate tube 12 is typically mounted in a glass working lathe that maintains the integrity of first seal 16 while rotating tube 12. The opposing end of tube 12 is coupled through a second rotating seal 18 to a vacuum exhaust system 19.

As shown in FIG. 1, an RF generator 30 is included in apparatus 10 and used to create a plasma of sufficient energy density within substrate 12 to provide the desired chemical reaction(s) with the delivered material. In most cases, generator 30 is mounted on a movable table (not show) to be traversed parallel to the axis of the mounted substrate tube, indicated by the double-ended arrow in FIG. 1. RF generator 30 comprises a resonant coil 32 that is positioned to surround a relatively short extent of tube 12, as shown in FIG. 1. An RF signal source (not shown) is coupled to resonant coil 32 and used to supply an RF signal thereto, thus creating the electro-magnetic field within tube 12. The combination of the incoming chemical reactants with the electro-magnetic field thus forms a plasma of an energy density sufficient to trigger the reaction and deposition of material on the inner surface of tube 12.

The creation of the plasma generates heat both within and outside of substrate tube 12. Heretofore, the thermal energy external to substrate tube 12 was generally lost and, as a result, the tube would exhibit fluctuations in its temperature.

In accordance with the present invention, the inclusion of an insulative covering 20 around at least a portion of substrate tube 12 functions to capture the heat and retain the external thermal energy, thus maintaining substrate tube 12 at a relatively constant temperature. By virtue of maintaining substrate tube 12 at a relatively constant temperature (preferably, the glass transition temperature of the material being deposited), the deposition will be smooth and bubble-free.

It is important that insulating covering 20 be formed of an appropriate material (such as a refractory material) that is able to withstand the temperatures associated with the PCVD process and provide the desired heat capture/reflection function. Materials such as, for example, silica, alumina, magnesia, zirconia or mullite may be used.

FIG. 2 is a side view of the combination of substrate tube 12 and insulative covering 20, illustrating in particular the location of a slit 22 along the side of insulative covering 20. The separation S between substrate tube 12 and insulating covering 20 is also shown in this view. The separation S between substrate tube 12 and insulative covering 20 is considered to be a matter of design choice in the determination of the amount of thermal energy that is desired to be captured and is impacted by parameters such as the temperature of the deposition process, the thickness of substrate tube 12, the material used to form insulative covering 20 and the inner diameter of the RF coil used to supply the energy to the plasma. Advantageously, the presence of this slit also allows for fabrication personnel to monitor the deposition process without being visually impaired by the insulating covering.

FIG. 3 is a side view of another embodiment of the present invention, where in this case insulating covering 20 comprises a pair of covering segments 23 and 24. In one embodiment. segments 23 and 24 may be fixed in place, providing fixed separations S-23 and S-24 between each segment and substrate tube 12 (these separations are not necessarily the same, although they may be, if desired). Alternatively, segments 23 and 24 may be moved “in” and “out” (with respect to the center of substrate tube 12) to create variable separations S(t) as a function of time. The variation in separation also varies the gap G between segments 23 and 24. The variation may be used to adjust the temperature of the substrate 12 as a function of the ongoing deposition process, allowing for real-time control of the substrate heating process.

FIG. 4 illustrates yet another embodiment of the present invention, where in this case insulative covering 20 is configured to create a variable separation S(L) between insulating covering 20 and substrate tube 12 along the length of tube 12. It is to be understood that various other arrangements of covering segments may be utilized and, in fact, the configuration of the segments may be modified during the actual deposition process to provide the thermal retention properties of the apparatus.

Indeed, it is to be understood that the above-described embodiments are illustrative of only a few of the many possible specific embodiments that can represent applications of the principles of the present invention. Numerous and varied other arrangements can be made by those skilled in the art without departing from the spirit and scope of the present invention as defined by the claims appended hereto.

What is claimed is:

1. Apparatus for performing plasma chemical vapor deposition along an inner surface of a substrate tube, the apparatus comprising
an insulative covering disposed along at least a longitudinal portion of the external surface of the substrate tube and separated a predetermined distance therefrom for capturing and retaining thermal energy created during the PCVD process.

2. Apparatus as defined in claim 1 wherein the insulative covering comprises at least one longitudinal slit formed therealong.

3. Apparatus as defined in claim 1 wherein the insulative covering comprises a single element.

4. Apparatus as defined in claim 1 wherein the insulative covering comprises multiple longitudinal segments.

5. Apparatus as defined in claim 1 wherein the predetermined separation distance is fixed.

6. Apparatus as defined in claim 1 wherein the predetermined separation distance is variable.

7. Apparatus as defined in claim 1 wherein the insulative covering comprises at least one material selected from the group consisting of: silica, alumina, magnesia, zirconia or mullite.

8. Apparatus as defined in claim 1 wherein the apparatus further comprises an RF generator and resonant coil for creating plasma energy within the substrate tube, with the insulative covering disposed within the resonant coil. 7
